(19) United States
(12) Patent Application Publication
(10) Pub. No.: US 2023/0082054 A1
(43) Pub. Date: Mar. 16, 2023

(54) DEVICE AND METHOD FOR CONTROLLING THE TEMPERATURE OF ELEMENTS IN MICRO-LITHOGRAPHIC PROJECTION EXPOSURE SYSTEMS

(71) Applicant: Carl Zeiss SMT GmbH, Oberkochen (DE)

(72) Inventors: Thomas Monz, Schlierbach (DE); Alexandre Kemp, Ludwigshafen am Rhein (DE); Johannes Lippert, Buch am Wald (DE)

(21) Appl. No.: 17/990,334

(22) Filed: Nov. 18, 2022

Related U.S. Application Data
(63) Continuation of application No. PCT/EP2021/058218, filed on Mar. 30, 2021.

(30) Foreign Application Priority Data
May 28, 2020 (DE) 102020206697.3

(51) Int. Cl. G03F 7/20

(52) U.S. Cl. CPC G03F 7/70891

(57) ABSTRACT

A micro-lithographic projection exposure system comprises an illumination unit and a projection lens with at least one element which is penetrated at least in regions by a temperature-control fluid line provided for conducting a temperature-control fluid for controlling the temperature of the element. The temperature-control fluid line is connected to a temperature-control fluid storage container. A temperature-control element for controlling the temperature of the temperature-control fluid is provided on or in the temperature-control fluid line. At least two of the elements are independently penetrated by a respective separate at least one of temperature-control fluid lines, or at least two different regions of the at least one element are penetrated independently by a respective separate at least one of the temperature-control fluid lines, or at least two of the elements are penetrated by the temperature-control fluid line. A corresponding method is provided.

### CROSS-REFERENCE TO RELATED APPLICATIONS

The present application is a continuation of, and claims benefit under 35 USC 120 to, international application PCT/EP2021/058218, filed Mar. 30, 2021, which claims benefit under 35 USC 119 of German Application No. 10 2020 206 697.3, filed May 28, 2020. The entire disclosure of these applications are incorporated by reference herein.

### FIELD

The present disclosure relates to items of equipment for controlling the temperature of elements in microlithographic projection exposure apparatuses. Moreover, the disclosure relates to a method for controlling the temperature of elements in microlithographic projection exposure apparatuses.

### BACKGROUND

Microlithography is used for producing microstructured components, such as for example integrated circuits or LCDs. The microlithography process is carried out in what is known as a projection exposure apparatus, which includes an illumination device and a projection lens. The image of a mask (=reticle) illuminated via the illumination device is projected here via the projection lens onto a substrate (e.g., a silicon wafer) coated with a light-sensitive layer (=photoresist) and arranged in the image plane of the projection lens, in order to transfer the mask structure to the light-sensitive coating of the substrate.

The terms microlithographic projection exposure apparatus, projection exposure apparatus, (EUV or DUV) system and lithographic scanner are used synonymously hereinafter.

In projection lenses designed for the DUV range, i.e., at wavelengths of, e.g., 193 nm or 248 nm, lens elements are typically used as optical elements for the imaging process. In order to achieve a higher resolution of lithographic optical units, projection lenses designed for the EUV range have been used for some years, the projection lenses being operated at wavelengths of, e.g., approximately 13.5 nm or 7 nm.

In such projection lenses designed for the EUV range, owing to the general lack of availability of suitable light-transmissive refractive materials, mirrors are generally used as optical elements for the imaging process. The mirrors operate either with almost normal incidence or with grazing incidence. Mirrors, on account of their reflective effect on light rays, can be significantly more position-sensitive than lens elements. In this regard, a mirror tilt with a factor of 2 can be translated into a change in ray direction, while what typically occurs in the case of a lens element is a considerable compensation of the change in the refractive ray direction influence between front and back sides.

A significant influence on the mirror shape often originates from the thermal expansion of the mirror material. Materials having low coefficients of thermal expansion such as Zerodur or ULE (ultra low expansion) are therefore commonly used for EUV mirrors. Such materials generally react to temperature changes significantly more weakly than glasses or quartz glass. Nevertheless, considerable error contributions can occur within the scope of the available aberration budget. The error contributions can be composed of effects of an inhomogeneous temperature distribution and inhomogeneities of the so-called zero crossing temperature (ZCT) in the volume of the material, for instance on account of a varying stoichiometry between SiO₂ and TiO₂ in the ULE material. Both local and global temperature changes vis-à-vis an envisaged operating temperature of the microlithographic projection exposure apparatus can cause aberrations, which can be corrected by manipulators only in part.

The operating state is often defined by an assumed maximum power of the EUV system at the operating wavelength, that is to say for example at a wavelength of 13.5 nm. If the maximum power is not reached, for instance because a reticle that is less highly reflective on average is used, then it is known for example to use infrared heaters to effect “top-up” heating and ensure that the mirrors are operated close to the averaged zero crossing temperature, where they are relatively insensitive on account of the quadratic deformation dependence on the temperature difference with respect to this temperature.

To transport the heat out of the projection lens and, very generally, to provide suitable temperature control for the elements of the projection lens, use can be made of temperature control fluids, typically water, which flow through the system at least regionally. FIG. 1 shows an EUV projection lens 640 according to the prior art. By way of its water cooling, the force frame 381, which carries the EUV mirrors 691, 692, 693, 694, adopts the overall temperature control of the EUV projection lens. There is only a single temperature control fluid line 602, which traverses the entire force frame 381. The four EUV mirrors 691, 692, 693 and 694 are connected to the force frame 381 by way of active mechanical bearings 695. The sensor frame 371 serves as a reference for the position measurement 625 of the EUV mirrors 691, 692, 693 and 694. Exemplary heat flows Q1 in the direction of the sensor frame 371 and Q2 in the direction of the mirror 692 are depicted. The EUV light 502 from the structure-bearing mask 120 (not depicted in FIG. 1) is reflected by the four EUV mirrors 691, 692, 693 and 694 and guided as EUV light 504 to the wafer 124 (not depicted in FIG. 1). The temperature control fluid line 602 guides the temperature control fluid through the force frame 381. The temperature control fluid line 602 is fed by a temperature control fluid storage container 615 for the force frame 381. A temperature control element 702 is arranged downstream of the force frame temperature control inlet 607. A temperature sensor 802 is arranged in the force frame 381. The temperature sensor 802 is coupled to the temperature control element 702. Coupling and closed-loop control have not been depicted in FIG. 1 for reasons of clarity (see FIG. 2 in this respect). After flowing through the temperature control fluid line 602, the temperature control fluid reaches the fluid storage container 615 via a force frame temperature control outlet 614. Should the temperature control element 702 be designed for simplicity to be able to heat only, the arrangement would have integrated therein what is known as a recooler system, or synonymously a recooler unit. The temperature control fluid would heat continuously without this recooler system. A recooler system is a piece of equipment which dissipates excess heat from a system via a heat exchanger. For the sake of clarity, this recooler system is not shown in FIG. 1.

In the process, the temperature control of the force frame 381 adopts the following tasks described below:
Initially the thermal stabilization of the force frame structure for stably positioning the mirrors. Rigid body movements can be compensated by actuators. However, the forces transferred to the mirrors by the actuators can produce wavefront aberrations as a result of mirror deformations. Moreover, the power additionally dissipated in the actuator units may lead to the thermal drift of the optical imaging.
Thermal stabilization of the mirror surround. Heating of the mirror surround can lead to wavefront aberrations. The reason for this lies in mirror deformations on account of deviations of the mirror temperature from the design temperature (zero crossing temperature) and deviations between production and measurement temperature.
Shielding the sensor frame (=reference for the mirror positioning) vis-à-vis thermal loads such as mirror preheating, exhaust heat of the actuators, encoders and sensors, in order thus to avoid a deformation of the measurement reference.
Closed-loop thermal control of the sensor frame in order to bring the sensor frame from a thermally uncontrolled state into the stable temperature controlled operating state. By way of example, this is used within the scope of a system recovery.
Closed-loop thermal control of the sensor frame during operation in order to keep the sensor frame within the tolerance limits in respect of the absolute temperature and temperature drift (derivative of the sensor frame temperature over time).

These five aforementioned features in relation to the temperature control of the force frame could, in general, previously be met by a compromise solution in terms of the thermal architecture in view of structure (force frame, sensor frame) heating and mirror heating.

FIG. 5 shows a DUV projection lens according to the prior art. The temperature control fluid line 452 passes through the cooler and sensor shield 450. The temperature control fluid line inlet 454 and the temperature control fluid line outlet 456 establish the connection to the DUV temperature control fluid storage container 460. A temperature sensor 806 is coupled to the temperature control element 706. Coupling and closed-loop control have not been depicted in FIG. 6 for reasons of clarity. The cooler and sensor shield 450 at least regionally encloses the DUV projection lens 404. Q5 is used to depict the heat flows of consumers in exemplary fashion and Q6 is used to depict the heat flows from the projection lens 404. The DUV light at the entry to the DUV projection lens 404 is labeled 408. The DUV light to the wafer 424 (not depicted in FIG. 5) is labeled 458.

Only a single temperature control fluid line 452 passes through the cooler and sensor shield 450. Generally, this cannot be used to bring and keep different regions of the cooler and sensor shield 450 at different temperature levels. This is also a compromise solution.

### SUMMARY

The present disclosure seeks to provide an improved item of equipment and an improved method, for example to improve the thermal stabilization of lithography systems.

According to the disclosure, a microlithographic projection exposure apparatus, for example for the DUV range or for the EUV range, is provided. The projection exposure apparatus comprises an illumination device and a projection lens having at least one element which at least regionally is traversed by at least one temperature control fluid line for guiding a temperature control fluid for the purposes of the temperature control of the element, with the temperature control fluid line being connected to at least one temperature control fluid storage container and with at least one temperature control element for controlling the temperature of the temperature control fluid being provided at or in the temperature control fluid line. In this case, at least two of the elements are each traversed independently of one another by at least one separate one of the temperature control fluid lines or at least two different regions of the at least one element are each traversed independently of one another by at least one separate one of the temperature control fluid lines or at least two of the elements are traversed by the temperature control fluid line. The aforementioned three options can allow different temperatures in different elements or different regions of one element.

In an embodiment, the at least two separate temperature control circuits are connected parallel to one another. This can allow independent temperature control of different elements or different regions of one element. Using this, it is possible to keep different regions of one element, for example of the force frame, at different temperatures. This consequently can provide the option of supplying individual regions with different supply temperatures. It is generally desirable to not distribute heat flows merging into the temperature control fluid on one side of an element within the whole system.

In an embodiment, two of the temperature control circuits are fed by a common temperature control fluid storage container. This can reduce the installation space involved.

In an embodiment, two of the temperature control circuits are fed by separate temperature control fluid storage containers. This can allow relatively exact setting of the temperature of the temperature control fluid in the respective temperature control fluid line.

Optionally, the temperature control fluid in the temperature control fluid storage containers is kept below the target temperature for the element to be subject to temperature control. This can allow a pure heater to be sufficient as a temperature control element. There is no need to cool the temperature control fluid. The heaters are arranged either at the outlet of the temperature control fluid storage container and/or at the inlet of the element to be subject to temperature control. Should the temperature control element only be able to heat, a recooler system or recooler unit would be integrated into the arrangement. The temperature control fluid would heat continuously without this recooler system.

The temperature control elements can be arranged outside of the vacuum, that is to say far away from the element to be subject to temperature control, at the temperature control fluid line. This can mean that the heaters do not disturb the interior of the projection lens. However, if the element needs to maintain the temperature very accurately, it is often desirable to place the heater as close as possible to the element. This also can reduce transport disturbances.

It is often desirable to measure the spatial temperature distribution for large elements such as the force frame for example; i.e., at least two temperature sensors are installed to and evaluated per element.

In an embodiment, at least two of the elements are connected in series and are traversed by one and the same temperature control fluid line. This can represent a relatively simple and space-saving solution.

In an embodiment, at least one temperature sensor for measuring the temperature at or in the element is provided in each element. The intention can be to use the temperature sensors to measure at the elements to be subject to temperature control. Depending on the control task, the temperature sensors, where possible, can be attached to those locations where the quantity to be regulated is measured as representatively as possible. By way of example, the mean temperature, the spatial temperature gradient or the temporal temperature gradient is determined. It is also possible to measure the inlet and outlet temperature, and thus measure the emitted or received heat flow. In the element, it is desirable that the temperature sensors must are not placed too close to the temperature control fluid line in order to help ensure that a measurement value is obtained that is representative for the thermal state of the element.

In an embodiment, at least one controller is provided for closed-loop control of the temperature control element, such as on the basis of the temperature measured by the temperature sensor at or in the element.

However, the elements may also be subject to temperature control without closed-loop control. In this case, the temperature of the respective element is brought close to the water temperature and hence close to the reference temperature as a result of the low thermal resistance (large cooler surfaces and/or a high thermal transfer coefficient of the contact between temperature control fluid and element) and a heat capacity flow that is as high as possible (high flow of water and/or high heat capacity of the fluid). Moreover, temperature gradients within the elements can be reduced by the spatial distribution of the cooling lines. High-frequency disturbances with frequencies above the control bandwidth of the thermal control loop of the element cooling, and the element deformations connected therewith, can thus be largely suppressed.

In an embodiment, the element is embodied as at least one
sensor frame,
force frame,
mirror support frame,
mirror, and/or
cooler and thermal shield.

In an embodiment, at least one cooler and thermal shield, for example with active temperature control and/or for example with passive temperature control, is arranged between at least two of the elements, for example between the force frame and the sensor frame. This can be desirable because coolers and thermal shields can relatively efficiently suppress thermal disturbances. Thus, high-frequency disturbances with a time constant of less than one hour can be suppressed by shielding the sensor frame. Active coolers and thermal shields can be traversed by a temperature control fluid. The temperature control fluid can remove the heat output from the system. The active cooler and thermal shield serves as a heat sink. Coolers and thermal shields with passive temperature control can delay and attenuate thermal effects due to thermal loads on the sensor frame. However, in general, they only form of a resistance that directs the heat flows in another direction. Thus, passive shields can guide the heat flows to the active shields which ultimately remove the heat output from the system. Passive closed-loop control actually means uncontrolled but supplied with a constant water temperature. However, the temperature set point of the elements with passive closed-loop control may also change as a result of active closed-loop control of other elements. Active closed-loop control means that at least one feedback controller controls the entry temperature.

Coolers and thermal shields can be used to carry the water in thin gaps. In general, the material is steel, aluminum or ceramic. Coolers and thermal shields usually have a high thermal conductivity.

In an embodiment, the beam path of an EUV light and at least one mirror can be accommodated by at least one cooler and thermal shield, such as with active temperature control.

In an embodiment, the temperature control fluid storage container and the temperature control element are arranged outside of the projection lens. This can avoid the introduction of additional thermal loads into the projection lens.

According to the disclosure, a method for controlling the temperature of at least one element in a microlithographic projection exposure apparatus provided for the EUV range or for the DUV range is provided. At least one temperature control fluid line is provided for guiding a temperature control fluid passing through the at least one element which is subject to temperature control using at least the following steps:
defining a target temperature of the at least one element,
measuring the actual temperature of the at least one element via at least one temperature sensor at or in the at least one element,
comparing the actual temperature with the target temperature via a comparator element,
reading the value of the deviation of the actual temperature from the targets temperature into a controller,
controlling the temperature of the temperature control fluid via at least one temperature control element provided at or in the at least one temperature control fluid line until the deviation of the actual temperature from the target temperature of the element is below a specified limit.

The identical method can also be applied for different temperature control of different regions of a single element.

Various exemplary embodiments are explained in more detail below with reference to the figures. The figures and the relative sizes of the elements shown in the figures in relation to one another should not be regarded as to scale. Rather, individual elements may be shown exaggerated in size or reduced in size to allow them to be represented better and for the sake of better understanding.

### BRIEF DESCRIPTION OF THE FIGURES

FIG. 1 shows a schematic representation of an EUV projection lens from the prior art.

FIG. 2 shows a schematic representation of an element from an EUV system that is subject to temperature control according to the disclosure.

FIG. 3 shows a schematic illustration of an EUV projection lens according to the disclosure with a parallel connection.

FIG. 4 shows a schematic illustration of an EUV projection lens according to the disclosure with a series connection.

FIG. 5 shows a schematic representation of a DUV projection lens from the prior art.

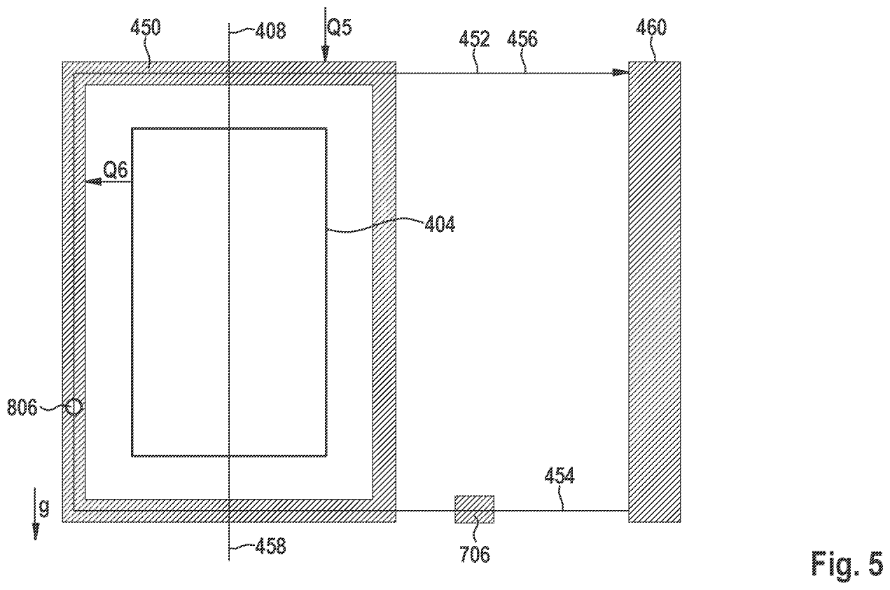

FIG. 6 shows a schematic illustration of a DUV projection lens according to the disclosure.

FIG. 7 shows a microlithographic projection exposure apparatus provided for the EUV range.

FIG. 8 shows a microlithographic projection exposure apparatus provided for the DUV range.

### EXEMPLARY EMBODIMENTS

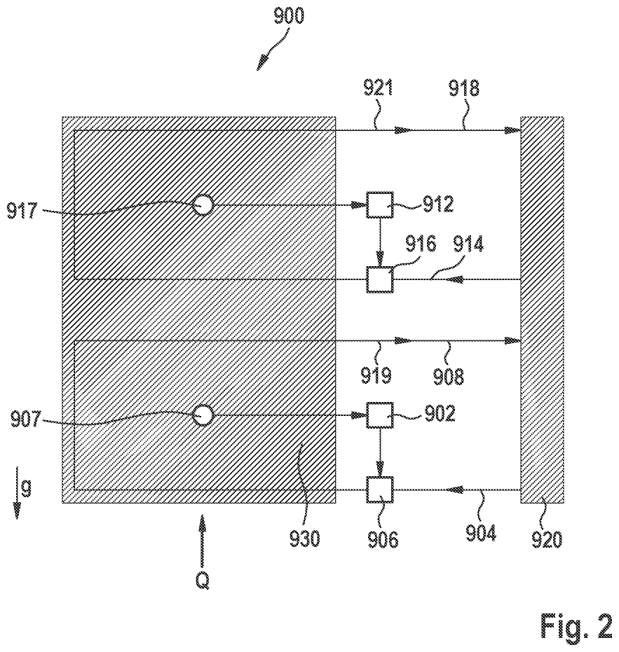

FIG. 2 shows a schematic representation of an element 930 from an EUV system that is subject to temperature control according to the disclosure. This is a parallel connection 900 of two temperature control circuits. By way of example, the element 930 can be a sensor frame, force frame or a mirror support frame. The temperature control fluid line 919 passes through the lower region of the element 930. The temperature control fluid line 921 passes through the upper region of the element 930. The temperature sensor 907 measures the temperature in the lower region of the element and transmits the measured temperature value to the controller 902, the latter controlling the temperature control element 906 which is arranged at the temperature control fluid line 919. The temperature control fluid line 919 is fed by the temperature control fluid storage container 920 and includes a temperature control fluid inlet 904 and a temperature control fluid outlet 908. Should the temperature control element 906 be designed for simplicity to be able to heat only, it would be desirable to integrate into the arrangement what is known as a recooler system, or synonymously a recooler unit. The temperature control fluid would heat continuously without this recooler system. For the sake of clarity, this recooler system is not shown in FIG. 2.

The temperature sensor 917 measures the temperature in the upper region of the element 930 and transmits the measured temperature value to the controller 912, the latter controlling the temperature control element 916 which is arranged at the temperature control fluid line 921. The temperature control fluid line 921 is likewise fed by the temperature control fluid storage container 920 and includes a temperature control fluid inlet 914 and a temperature control fluid outlet 918. Each of the two temperature control circuits has a dedicated temperature control fluid storage container in an embodiment not shown here.

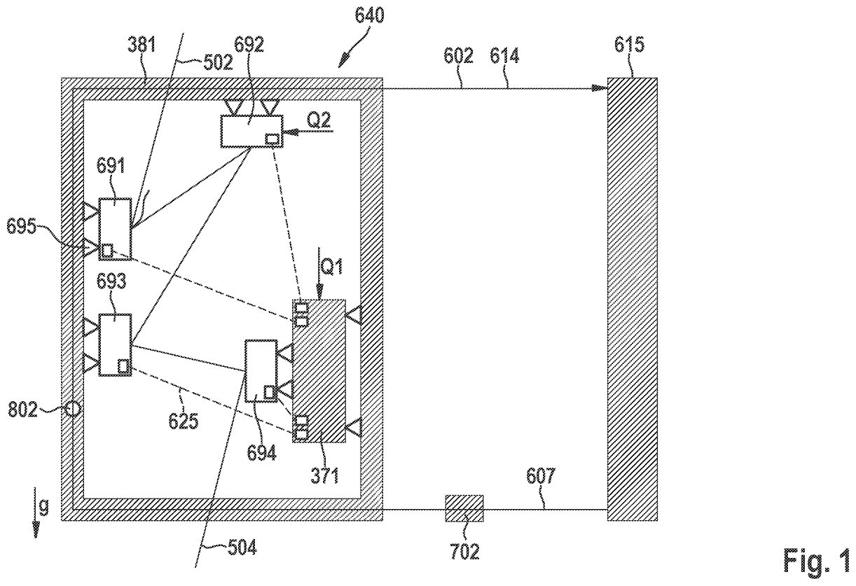

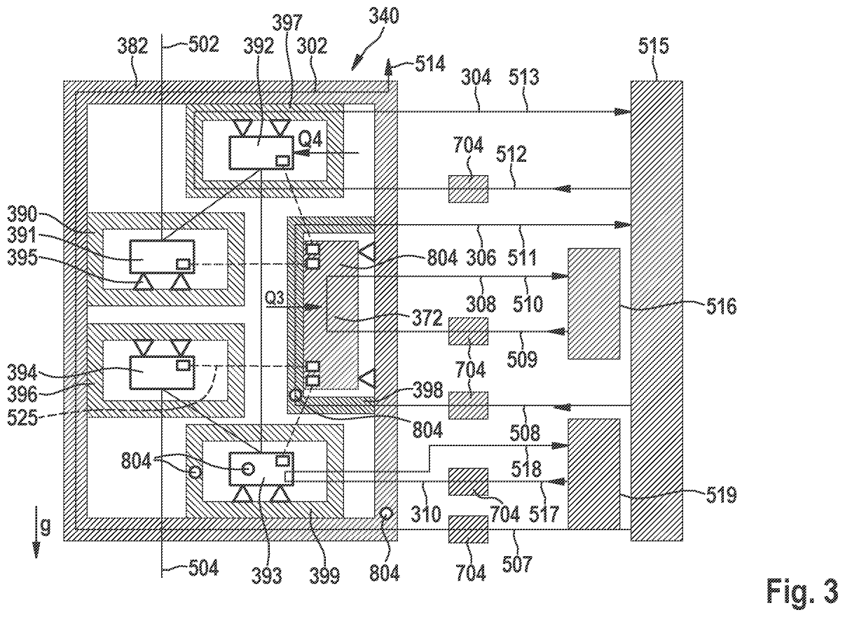

FIG. 3 shows a schematic illustration of an EUV projection lens 340 according to the disclosure with a parallel connection. To reduce the thermally induced drifts and wavefront aberrations, the five problems portrayed in the prior art (see the explanations in relation to FIG. 1) are solved according to the disclosure by a plurality of different temperature control and shielding systems. The heat flows Q3 in the direction of the sensor frame 372 and Q4 in the direction of the mirror 392 are depicted merely in exemplary fashion. The mirrors 391, 392, 393, 394 are fastened to active mechanical bearings 395. The temperature control fluid line 302 passes through the force frame 382. A temperature sensor 804 measures the temperature in the force frame 382. A temperature control element 704 controls the temperature of the temperature control fluid until the target value of the temperature of the force frame 382 is reached. The control used to this end is not shown in FIG. 3 for reasons of overall clarity. With regard to the closed-loop control, reference is made to the illustration of FIG. 2. The temperature control fluid line 306 passes through the cooler and thermal shield 398. The cooler and thermal shield 398 thermally shields the sensor frame 372. The temperature control line 304 passes through the mirror support frame 397. The sensor frame 372 is traversed by the temperature control fluid line 308, which is fed by its own fluid storage container 516. The mirror 393 is traversed by its own temperature control fluid line 310, which is fed by its own fluid storage container 519. Each element comprises at least one temperature sensor 804. A common fluid storage container 515 is assigned to all aforementioned temperature control fluid lines 302, 304, 306. The EUV light 502 from the structure-bearing mask 120 (not depicted in FIG. 3) is reflected at the mirrors and leaves the lens as EUV light 504 in the direction of the wafer 124 (not depicted in FIG. 3). In summary, the following should be noted:
The thermal stabilization of the force frame 382 is achieved by controlled water cooling. The latter may consist of a plurality of cooling circuits.
The temperature control of the mirror surround is achieved by water cooling of the mirror support frames 390, 396, 397, 399.
The beam path and the optical surfaces of the mirror are housed by a single or multiple layer, actively cooled cooling shield 398 such that stray light and thermal conduction from the beam path to the sensor frame 372 are suppressed. This has not been depicted in FIG. 3 for reasons of clarity. The thermal output from the force frame 382 to the sensor frame 372 is shielded by an active or passive cooling shield (CS) 398.
Thermally controlling the sensor frame 372 is implemented by way of actively controlled water cooling of the sensor frame 372.

Design measures for suppressing a thermal draft of the sensor frame 372 can be divided as follows in terms of their effect over time:
Disturbances with time constants of more than one hour can be suppressed by thermal control of the sensor frame and/or force frame.
Disturbances of the sensor frame with time constants below one hour can be suppressed by shielding the sensor frame by way of cooled or passive cooling shields between the force frame and the sensor frame.

Cooling the sensor frame with water is very sluggish, that is to say has a long time constant. That is to say, the disturbance can be subject to long wavelength compensation.

High-frequency disturbances are suppressed by the inner cooler; thermal output would act on the sensor frame without the inner cooler.

Moreover, different control tasks within the EUV projection lens, for example absolute temperature stability in the case of the mirror support frame and/or drift stability (force frame, mirror, sensor frame) in the case of the cooling shield, can be followed with largely independent control loops. This allows a reduction in the thermally induced drifts and wavefront aberrations.

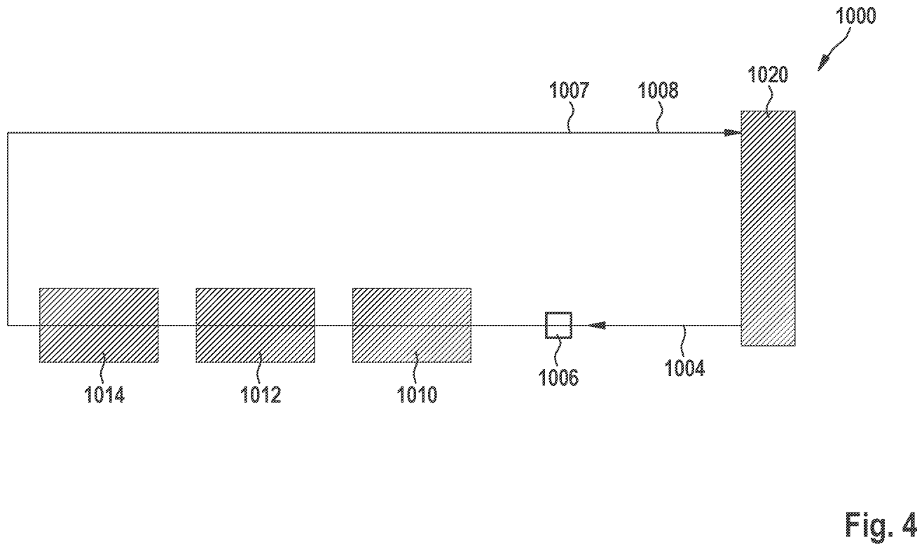

FIG. 4 shows a schematic illustration of an EUV projection lens according to the disclosure with a series connection. A single temperature control fluid storage container 1020 feeds the only temperature control fluid line 1007. A temperature control element 1006 is arranged on the temperature control fluid line 1007 downstream of the temperature control fluid inlet 1004. Three elements of a series are connected in exemplary fashion. In the present example, the fluid initially flows through the cooler and temperature shield 1010, which is also referred to as an inner cooler. Then, the fluid flows through the force frame 1012. Last, the fluid flows through the mirror support frame 1014. The inner cooler 1010 is subject to temperature control first as it is arranged closest to the thermally most sensitive sensor frame. The element with the highest thermal load, the mirror support frame 1014—on account of the mirror preheating and the exhaust heat of the actuators—is located at the end to avoid dragging the thermal output within the entire system by way of the temperature control fluid. The force frame 1012 is placed therebetween.

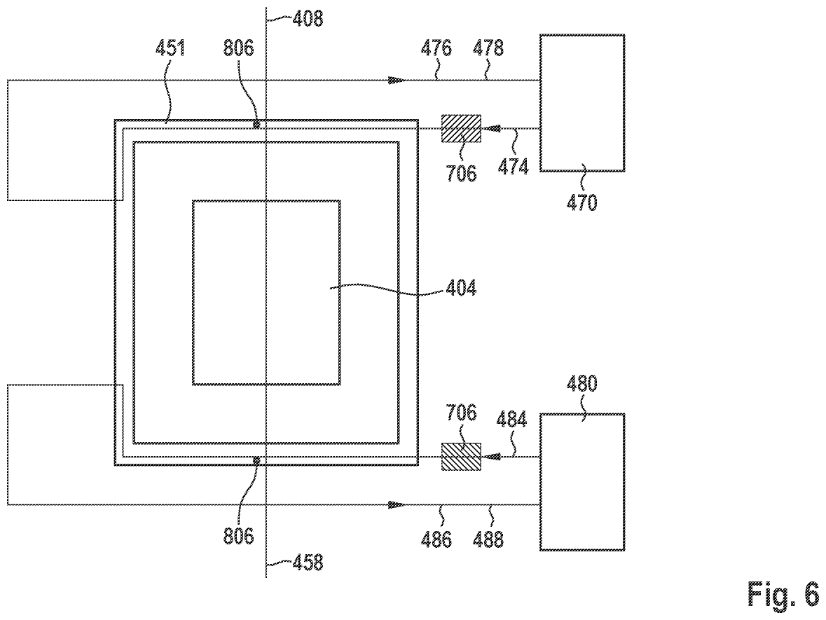

FIG. 6 shows a schematic illustration of a DUV projection lens according to the disclosure. Two independent temperature control fluid lines 476, 486 pass through the cooler and sensor shield 451. The upper temperature control fluid line 476 is fed by the temperature control fluid storage container 470. The lower temperature control fluid line 486 is fed by the temperature control fluid storage container 480. Thus, two regions of the cooler and sensor shield 451 can be subject to temperature control independently of one another. Each of the two regions has a temperature sensor 806 and a temperature control element 706. The upper temperature control fluid line 476 has an inlet 474 and an outlet 478. The lower temperature control fluid line 486 has an inlet 484 and an outlet 488. Controlling the temperatures of the two regions is not depicted in FIG. 6 for reasons of clarity.

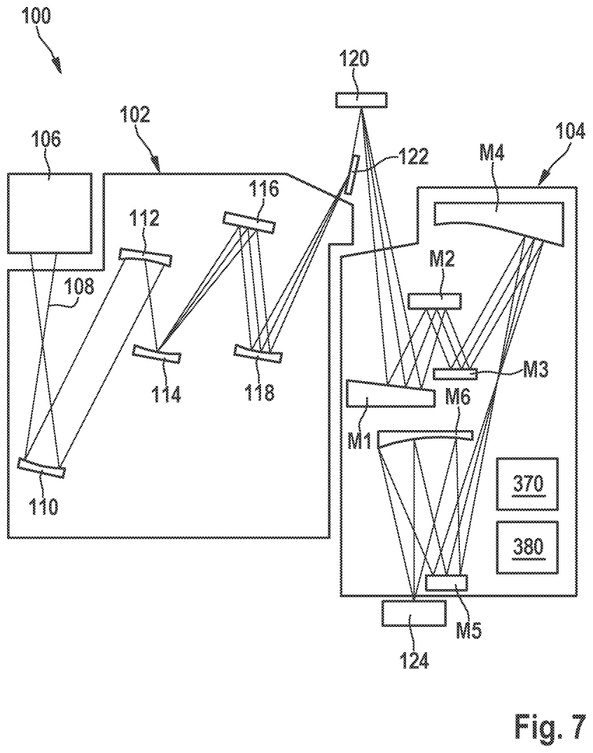

The EUV lithography apparatus 100 depicted in FIG. 7 comprises a beam-shaping and illumination system 102 and a projection system 104. The beam-shaping and illumination system 102 and the projection system 104 are each provided in a vacuum housing, indicated in FIG. 7, with each vacuum housing being evacuated with the aid of an evacuation device (not shown). The vacuum housings are surrounded by a machine room (not depicted), in which the drive equipment for mechanically moving or setting the optical elements are provided. Furthermore, electrical controllers and the like may also be provided in the machine room.

The EUV lithography apparatus 100 comprises an EUV light source 106. A plasma source (or a synchrotron) which emits radiation 108 in the EUV range, for example in the wavelength range of between 5 nm and 20 nm, can be provided, for example, as the EUV light source 106. In the beam-shaping and illumination system 102, the EUV radiation 108 is focused and the desired operating wavelength is filtered out from the EUV radiation 108. The EUV radiation 108 generated by the EUV light source 106 has a relatively low transmissivity through air, for which reason the beam-guiding spaces in the beam-shaping and illumination system 102 and in the projection system 104 are evacuated.

The beam shaping and illumination system 102 illustrated in FIG. 7 has five mirrors 110, 112, 114, 116, 118. After passing through the beam-shaping and illumination system 102, the EUV radiation 108 is directed onto the photomask (reticle) 120. The photomask 120 is likewise in the form of a reflective optical element and may be arranged outside the systems 102, 104. Furthermore, the EUV radiation 108 may be directed onto the photomask 120 via a mirror 122. The photomask 120 has a structure which is imaged onto a wafer 124 or the like in a reduced fashion via the projection system 104.

The projection system 104 (also referred to as projection lens) has six mirrors M1-M6 for imaging the photomask 120 onto the wafer 124. It should be noted that the number of mirrors of the EUV lithography apparatus 100 is not restricted to the number illustrated. More or fewer mirrors could also be provided. The force frame 380, which substantially carries the mirrors of the projection lens, and the sensor frame 370, which substantially serves as a reference for the position of the mirrors of the projection lens, are shown roughly schematically. Furthermore, the mirrors, as a rule, are curved on their front side for beam shaping.

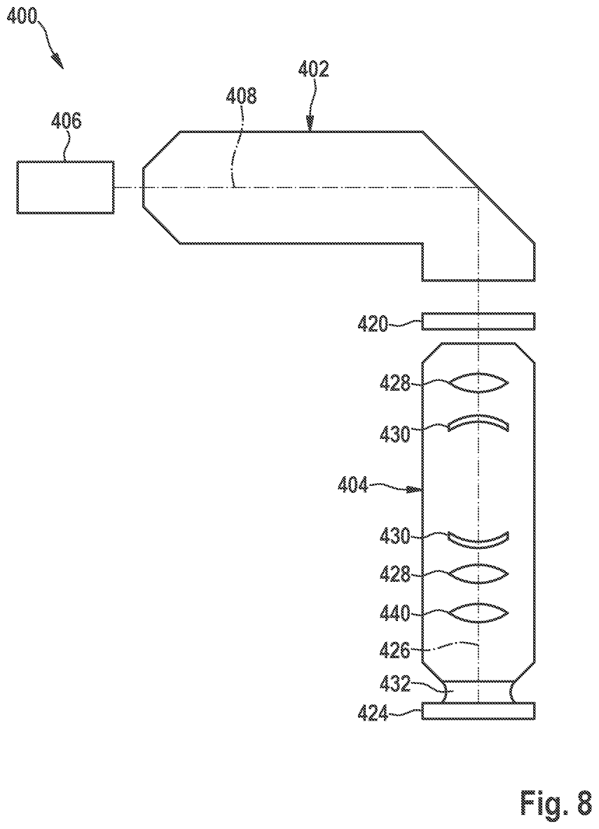

FIG. 8 shows a schematic illustration of a microlithographic projection exposure apparatus according to the disclosure for the DUV range 400. The DUV projection exposure apparatus 400 comprises a beam shaping and illumination device 402 and a projection lens 404. In this case, DUV stands for “deep ultraviolet” and denotes a wavelength of the working light of between 30 and 250 nm.

The DUV projection exposure apparatus 400 comprises a DUV light source 406. For example, an ArF excimer laser that emits radiation 408 in the DUV range at for example 193 nm, may be provided as the DUV light source 406.

The beam shaping and illumination device 402 illustrated in FIG. 8 guides the DUV radiation 408 onto a photomask 420. The photomask 420 is formed as a transmissive optical element and may be arranged outside the beam shaping and illumination device 402 and the projection lens 404. The photomask 420 has a structure of which a reduced image is projected onto a wafer 424 or the like via the projection lens 404.

The projection lens 404 has a number of lens elements 428, 440 and/or mirrors 430 for projecting an image of the photomask 420 onto the wafer 424. In this case, individual lens elements 428, 440 and/or mirrors 430 of the projection lens 404 may be arranged symmetrically in relation to the optical axis 426 of the projection lens 404. It should be noted that the number of lens elements and mirrors of the DUV projection exposure apparatus 400 is not restricted to the number shown. More or fewer lens elements and/or mirrors may also be provided. Furthermore, the mirrors are generally curved on their front side for beam shaping.

An air gap between the last lens element 440 and the wafer 424 may be replaced by a liquid medium 432 which has a refractive index of >1. The liquid medium 432 may be for example high-purity water. Such a structure is also referred to as immersion lithography and has an increased photolithographic resolution.

Even though the disclosure has been described on the basis of specific embodiments, numerous variations and alternative embodiments will be apparent to a person skilled in the art, for example through combination and/or exchange of features of individual embodiments. Accordingly, it will be apparent to a person skilled in the art that such variations and alternative embodiments are also encompassed by the present disclosure, and the scope of the disclosure is restricted only within the scope of the appended patent claims and the equivalents thereof.

The following terms are used synonymously:

EUV system is used synonymously with EUV projection exposure apparatus and with microlithographic projection exposure apparatus for the EUV range. DUV system is used synonymously with DUV projection exposure apparatus and microlithographic projection exposure apparatus for the DUV range. Where cooling is used, temperature control, that is to say cooling and/or heating, should also be comprised. Thus, fluid, temperature control fluid and cooling fluid are used synonymously. Additionally, cooling shield and cooler and temperature shield are used synonymously. Photomask and reticle are used (synonymously. Wafer and substrate coated with a light-sensitive layer (photoresist) are used synonymously. Sensor frame is abbreviated SFr. Force frame is abbreviated FFr. Mirror support frame is abbreviated MSF.

### LIST OF REFERENCE SIGNS

100 (Microlithographic) projection exposure apparatus for the EUV range (=EUV system)
102 EUV (beam shaping and) illumination device
104 EUV projection lens having six mirrors (M1 to M6)
106 EUV light source
108 EUV radiation
110, 112, 114, 116, 118 Mirrors of the EUV illumination device 102
120 Photomask, reticle (reflective)
122 Mirror
124 Wafer (=substrate coated with a light-sensitive layer (photoresist))
302, 304, 306, 308, 310 Temperature control fluid line
340 EUV projection lens having four mirrors (391, 392, 393, 394)
370, 371, 372 Sensor frame (SFr)
380, 381, 382 Force frame (FFr)
390 Mirror support frame (MSF)
395 Active mechanical bearing
396 Mirror support frame (MSF)
397 Mirror support frame (MSF)
398 Cooler and thermal shield (CS)
399 Mirror support frame (MSF)
400 (Microlithographic) projection exposure apparatus for the DUV range (=DUV system)
402 DUV (beam shaping and) illumination device
404 DUV projection lens
406 DUV light source
408 DUV light at the entry to the DUV projection lens 404
420 Photomask, reticle (transmitting)
424 Wafer
426 Optical axis of the projection lens 404
428 Lens elements
430 Mirror
432 Liquid medium
440 Last lens element
450 DUV cooler and thermal shield (prior art)
451 DUV cooler and thermal shield
452 Temperature control fluid line
454 Temperature control fluid inlet
456 Temperature control fluid outlet
458 DUV light to the wafer
460 Temperature control fluid storage container
470 Temperature control fluid storage container
474 Temperature control fluid inlet
476 Temperature control fluid line
478 Temperature control fluid outlet
480 Temperature control fluid storage container
484 Temperature control fluid inlet
486 Temperature control fluid line
488 Temperature control fluid outlet
502 EUV light from the structure-bearing mask 321
504 EUV light in the direction of the wafer 124
507 Force frame temperature control inlet
508 Surface temperature control inlet
509 Sensor frame temperature control inlet
510 Sensor frame temperature control outlet
511 Surface temperature control outlet
512 Mirror support frame temperature control inlet
513 Mirror support frame temperature control outlet
514 Force frame temperature control outlet
515 Fluid storage container for FFr/MSF/CS
516 Fluid storage container for SFr
517 Mirror temperature control inlet
518 Mirror temperature control outlet
519 Fluid storage container for mirror
525 Position measurement
602 Temperature control fluid line
607 Force frame temperature control inlet
614 Force frame temperature control outlet
615 Fluid storage container for force frame
625 Position measurement
640 EUV projection lens having four mirrors (691, 692, 693, 694)
695 Active mechanical bearing
Q1 Heat flows in the direction of the sensor frame 371
Q2 Heat flows in the direction of the mirror 692
Q3 Heat flows in the direction of the sensor frame 372
Q4 Heat flows in the direction of the mirror 392
Q5 Heat flows of consumers (DUV)
Q6 Heat flows from the DUV projection lens 404
702 Temperature control element
704 Temperature control element
706 Temperature control element
802 Temperature sensor (EUV, prior art)
804 Temperature sensor (EUV)
806 Temperature sensor (DUV)
900 Parallel connection
902 Controller
904 Temperature control fluid inlet
906 Temperature control element
907 Temperature sensor
908 Temperature control fluid outlet
912 Controller
914 Temperature control fluid inlet
916 Temperature control element
917 Temperature sensor
918 Temperature control fluid outlet
919 Temperature control fluid line
920 Temperature control fluid storage container
921 Temperature control fluid line
930 Element (SFr, FFr, MSF)
1000 Series connection
1004 Temperature control fluid inlet
1006 Temperature control element
1007 Temperature control fluid line
1008 Temperature control fluid outlet
1010 Element 1, for example cooler and thermal shield
1012 Element 2, for example force frame
1014 Element 3, for example mirror support frame
1020 Temperature control fluid storage container

What is claimed is:

1. An apparatus, comprising:
an illumination device;
a projection lens comprising first and second elements;
a first fluid line at least regionally traversing the first element to guide a fluid to control a temperature of the first element;
a first fluid storage container connected to the first fluid line;
a first temperature control element configured to control a temperature of the fluid being provided to the first fluid line or a temperature of the fluid in the first fluid line,
wherein the apparatus is a microlithographic projection exposure apparatus, and at least one of the following holds:
the apparatus comprises a second fluid line at least regionally traversing the second element to guide a fluid to control a temperature of the second element;
the first fluid line independently traverses at least two different regions of the first element; and
the first fluid line traverses the first and second elements.

2. The apparatus of claim 1, further comprising:
a second fluid line connected to the first fluid storage container; and
a second temperature control element configured to control a temperature of the fluid being provided to the first fluid line or a temperature of the fluid in the first fluid line.

3. The apparatus of claim 1, further comprising:
a second fluid line connected to the first fluid storage container;
a first control circuit connected to the first fluid line; and
a second control circuit connected to the second fluid line.

4. The apparatus of claim 3, wherein one of the following holds:
each of the first and second control circuits is connected to the first fluid storage container; and
the apparatus further comprises a second fluid storage container, the first control circuit is connected to the first fluid storage container, and the second control circuit is connected to the second fluid storage container.

5. The apparatus of claim 1, wherein the first and second elements are connected in series and are traversed by the first fluid line.

6. The apparatus of claim 1, further comprising a temperature sensor, wherein the temperature sensor is adjacent the first element to measure a temperature adjacent to the first element, or the temperature sensor is in the first element to measure a temperature in the element.

7. The apparatus of claim 6, further comprising a controller to provide closed-loop control of the first temperature control element based on a temperature measured by the temperature sensor.

8. The apparatus of claim 1, wherein the first and second elements each comprise at least one member selected from the group consisting of a sensor frame, a force frame, a mirror support frame, a mirror, and a cooler and thermal shield.

9. The apparatus of claim 1, further comprising a cooler and thermal shield between the first and second elements.

10. The apparatus of claim 9, wherein the apparatus comprises a mirror, the apparatus is an EUV microlithographic projection exposure apparatus, and a beam path of EUV light and the mirror are accommodated by the cooler and thermal shield.

11. The apparatus of claim 1, wherein the first fluid storage container and the temperature control element are outside of the projection lens.

12. The apparatus of claim 1, wherein the apparatus is an EUV microlithographic projection exposure apparatus.

13. The apparatus of claim 1, wherein the apparatus is a DUV microlithographic projection exposure apparatus range.

14. A method for controlling a temperature of an element in a microlithographic projection exposure apparatus comprising a fluid line to guide a fluid passing through the element, the method comprising:
measuring a temperature of the element;
comparing the measured temperature of the element with a target temperature of the element;
controlling a temperature of the fluid using a control element at or in the fluid line until a difference between the measured temperature of the element and the target temperature of the element is below a specified limit.

15. The method of claim 14, further comprising determining the target temperature of the element.

16. The method of claim 15, wherein the temperature of the element is measured using a temperature sensor at or in the element.

17. The method of claim 16, further comprising using a closed-loop control circuit to control the temperature of the fluid.

18. The method of claim 14, wherein the temperature of the element is measured using a temperature sensor at or in the element.

19. The method of claim 19, further comprising using a closed-loop control circuit to control the temperature of the fluid.

20. The method of claim 14, further comprising using a closed-loop control circuit to control the temperature of the fluid.
